(19) United States
(12) Patent Application Publication
(10) Pub. No.: US 2024/0395543 A1
(43) Pub. Date: Nov. 28, 2024

(54) WAFER AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Hisashi YOSHIDA, Kawasaki (JP); Ryoma KANEKO, Ota (JP); Hajime NAGO, Yokohama (JP); Toshiki HIKOSAKA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 18/585,412

(22) Filed: Feb. 23, 2024

(30) Foreign Application Priority Data
May 22, 2023 (JP) 2023-083722
Jan. 24, 2024 (JP) 2024-008907

(51) Int. Cl. H01L 21/02; H01L 29/20; H01L 29/778

(52) U.S. Cl. CPC H01L 21/0243; H01L 29/2003; H01L 29/7786

(57) ABSTRACT

According to one embodiment, a wafer includes a silicon substrate, a first layer, and a plurality of structures. The first layer includes aluminum and nitrogen. The plurality of structures are provided between a part of the silicon substrate and a part of the first layer in a first direction from the silicon substrate to the first layer. The plurality of structures includes a first element and silicon. The first element includes at least one selected from the group consisting of Ni, Cu, Cr, Mn, Fe and Co. Another part of the first layer is in contact with another part of the silicon substrate.

### CROSS-REFERENCE TO RELATED APPLICATIONS

This application is based upon and claims the benefit of priority from Japanese Patent Application No. 2023-083722, filed on May 22, 2023, and Japanese Patent Application No. 2024-008907, filed on Jan. 24, 2024; the entire contents of which are incorporated herein by reference.

### FIELD

Embodiments described herein generally relate to a wafer and a semiconductor device.

### BACKGROUND

For example, semiconductor devices are formed using wafers including nitride. Improvements in characteristics are desired in wafers and semiconductor devices.

### BRIEF DESCRIPTION OF THE DRAWINGS

FIG. 1 is a schematic cross-sectional view illustrating a wafer according to a first embodiment;

FIG. 2 is an electron microscope image illustrating the wafer according to the first embodiment;

FIG. 3 is a microscope image illustrating the wafer according to the first embodiment;

FIGS. 4A to 4C are microscopic images illustrating the wafer according to the first embodiment;

FIG. 5 is an image showing positions in the wafer according to the first embodiment;

FIG. 6 is a graph illustrating element concentrations in the wafer according to the first embodiment;

FIG. 7 is a graph illustrating element concentrations in the wafer according to the first embodiment;

FIG. 8 is a graph illustrating element concentrations in the wafer according to the first embodiment;

FIG. 9 is a graph illustrating element concentrations in the wafer according to the first embodiment;

FIG. 10 is a graph illustrating element concentrations in the wafer according to the first embodiment;

FIG. 11 is an elemental profile illustrating the wafer according to the first embodiment;

FIG. 12 is an elemental profile illustrating the wafer according to the first embodiment;

FIG. 13 is a schematic cross-sectional view illustrating a semiconductor device according to a second embodiment; and

FIG. 14 is a schematic cross-sectional view illustrating a semiconductor device according to the second embodiment.

### DETAILED DESCRIPTION

According to one embodiment, a wafer includes a silicon substrate, a first layer, and a plurality of structures. The first layer includes aluminum and nitrogen. The plurality of structures are provided between a part of the silicon substrate and a part of the first layer in a first direction from the silicon substrate to the first layer. The plurality of structures includes a first element and silicon. The first element includes at least one selected from the group consisting of Ni, Cu, Cr, Mn, Fe and Co. Another part of the first layer is in contact with another part of the silicon substrate.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

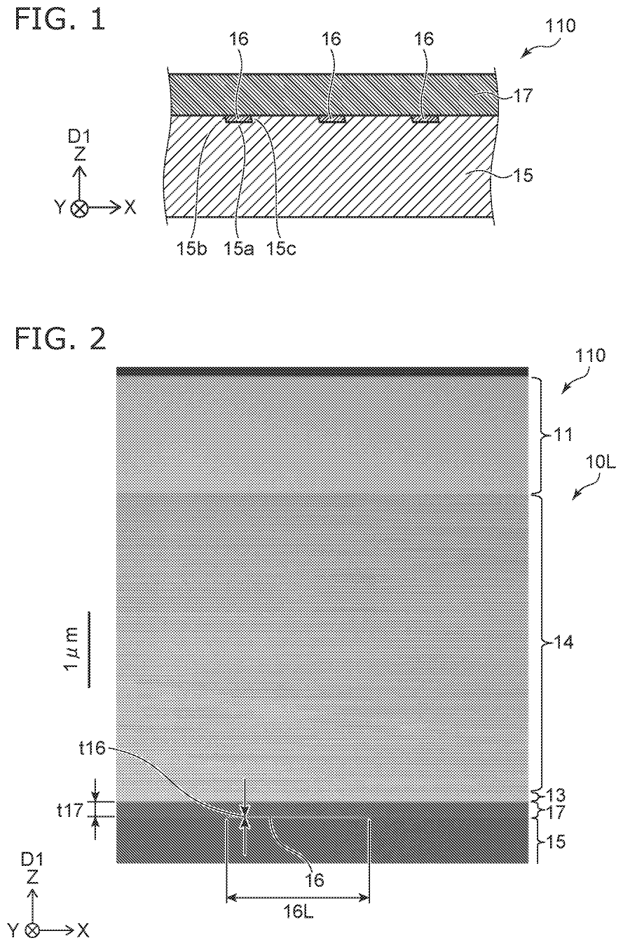

FIG. 1 is a schematic cross-sectional view illustrating a wafer according to a first embodiment.

As shown in FIG. 1, a wafer 110 according to the embodiment includes a silicon substrate 15, a first layer 17, and a plurality of structures 16. The first layer 17 includes aluminum and nitrogen. The first layer 17 is, for example, an AlN layer.

A first direction D1 from the silicon substrate 15 to the first layer 17 is defined as a Z-axis direction. One direction perpendicular to the Z-axis direction is defined as an X-axis direction. A direction perpendicular to the Z-axis direction and the X-axis direction is defined as a Y-axis direction.

The first layer 17 is layered parallel to the X-Y plane. The silicon substrate 15 extends along the X-Y plane.

The plurality of structures 16 are provided between a part of the silicon substrate 15 and a part of the first layer 17 in the first direction D1. For example, another part of the first layer is in contact with another part of the silicon substrate 15.

For example, the silicon substrate 15 includes a first silicon region 15a, a second silicon region 15b and a third silicon region 15c. The plurality of structures 16 are provided between the first silicon region 15a and the first layer 17 in the first direction D1. One of the plurality of structures 16 is provided between the second silicon region 15b and the third silicon region 15c in a direction crossing the first direction D1. The direction crossing the first direction D1 is an arbitrary direction along the X-Y plane. For example, the plurality of structures 16 are island-shaped. The plurality of structures 16 are discontinuous with each other.

The plurality of structures 16 include a first element and silicon. The first element includes at least one selected from the group consisting of Ni, Cu, Cr, Mn, Fe and Co. The first element is, for example, a transition element. For example, the plurality of structures 16 include a compound including Ni and silicon. The plurality of structures 16 include, for example, crystal.

A plurality of such structures 16 are provided in a distributed manner between the silicon substrate 15 and the first layer 17 (AlN layer). Thereby, stress in the wafer 110 is relaxed, and cracks, for example, are suppressed.

For example, a reference example may be considered in which a continuous layer including Ni or the like is provided between the silicon substrate 15 and the first layer 17. In this case, since a layer including Ni or the like is continuously provided between the silicon substrate 15 and the first layer 17, crystallinity becomes low due to a mismatch of lattice constants.

In contrast, in the embodiment, a plurality of structures being discontinuous are provided. This relaxes the lattice constant mismatch. As a result, a plurality of structures 16 having high crystallinity are obtained. By forming the first layer on the plurality of structures 16 having highly crystalline and the silicon substrate 15, the first layer 17 and the nitride layer formed thereon having high crystallinity can be obtained. According to the embodiment, high crystallinity can be obtained while suppressing cracks. According to the embodiment, a wafer with improved characteristics can be provided.

As described above, for example, the plurality of structures 16 include a compound including Ni and silicon. The coefficient of thermal expansion of the silicon substrate 15 is approximately 3.6×10⁻⁶/K. The thermal expansion coefficient of the first layer 17 (AlN) is approximately 4.2×10⁻⁶/K. The coefficient of thermal expansion of NiSi₂ is approximately 14.4×10⁻⁶/K. Thus, the coefficient of thermal expansion of NiSi₂ is large. As a result, for example, the tensile stress generated when the temperature is lowered to room temperature after various layers are formed on the wafer 110 at a high temperature can be reduced.

The lattice constant of the silicon substrate 15 is 0.543 nm. The lattice constant of the first layer 17 (AlN) is 0.311 nm. The lattice constant of NiSi₂ is 0.540 nm. The lattice constant of NiSi₂ is equivalent to the lattice constant of the silicon substrate 15.

In one example, the plurality of structures 16 are obtained by heat-treating the silicon substrate 15 in an environment including the first element (for example, Ni). For example, a trace amount of the first element adheres to the surface of the silicon substrate 15 by heat treatment. The first element may be incorporated into the silicon substrate 15 by heat treatment. At this time, if a large amount of the first element adheres to the surface of the silicon substrate 15, a continuous film will be formed and the plurality of structures 16 being discontinuous will not be obtained. The wafer 110 is obtained by forming the first layer 17 on the silicon substrate 15 on which the plurality of structures 16 are provided. The first layer 17 can be formed, for example, by a method such as MOCVD (Metal Organic Chemical Vapor Deposition).

By providing the plurality of structures 16 being discontinuous, the crystallinity of the plurality of structures 16 can be improved. On the other hand, if a continuous film is provided, the crystallinity deteriorates. When the first layer 17 (AlN) is formed on the deteriorated continuous film, the crystallinity of the first layer 17 (AlN) deteriorates. By forming the first layer 17 (AlN) on the plurality of structures 16 being discontinuous, it is easy to obtain the first layer 17 (AlN) with a 20 high quality.

In the embodiments, the plurality of structures 16 may include, for example, a compound of Cu and silicon. In this case as well, high crystallinity can be obtained while suppressing cracks. In addition, the plurality of structures 16 may include, for example, a compound of silicon and at least one selected from the group consisting of Ni, Cu, Cr, Mn, Fe, and Co.

FIG. 2 is an electron microscope image illustrating the wafer according to the first embodiment.

FIG. 2 is a HAADF-STEM (High Angle Annular Dark-Field Scanning Transmission Electron Microscopy) image of a cross section of the wafer 110. In FIG. 2, one of the plurality of structures 16 is illustrated. The thickness of the first layer 17 along the first direction D1 is defined as a first layer thickness t17. The thickness of one of the plurality of structures 16 along the first direction D1 is defined as structure thickness t16. The structure thickness t16 is thinner than the first layer thickness t17.

The structure thickness t16 is, for example, not less than nm and not more than 30 nm. Due to the structure thickness t16 being thin, high crystallinity can be easily obtained in the plurality of structures 16. If the structure thickness t16 is excessively thick, the crystallinity may become low. If the structure thickness t16 is too thin, the effect of stress relaxation will be reduced, and the effect of suppressing cracks will be reduced.

As shown in FIG. 2, a length of one of the plurality of structures 16 in a direction perpendicular to the first direction D1 is defined as a structure length 16L. In the embodiment, the structure length 16L is, for example, not less than 200 nm and not more than 5000 nm. If the structure length 16L is excessively long, the crystallinity may become low, for example. If the structure length 16L is too short, the effect of suppressing cracks may be reduced.

As shown in FIG. 2, the wafer 110 may further include a nitride layer 10L. The first layer 17 is provided between the silicon substrate 15 and the nitride layer 10L. The nitride layer 10L includes nitrogen and at least one selected from the group consisting of Al and Ga. The nitride layer 10L may include, for example, an AlGaN layer 13, a stacked structure 14, a first nitride region 11, and the like. In the embodiments, by providing the plurality of structures 16, high crystallinity can be obtained in the nitride layer 10L. An example of the nitride layer 10L will be described later.

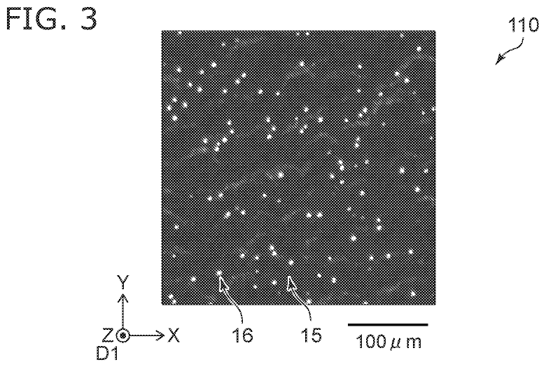

FIG. 3 is a microscope image illustrating the wafer according to the first embodiment.

FIG. 3 is an optical micrograph image of the wafer 110. FIG. 3 illustrates the silicon substrate 15 and the plurality of structures 16 before the first layer 17 is formed.

A plurality of bright points illustrated in FIG. 3 correspond to the plurality of structures 16. The dark areas in the image of FIG. 3 correspond to areas where the structures 16 are absent. The dark areas correspond to the surface of the silicon substrate 15, for example. Dark areas correspond to nitride layer 10L, for example, where the structures 16 are absent. As shown in FIG. 3, the plurality of structures 16 are island-shaped (dot-shaped).

For example, the density of the plurality of structures 16 in the X-Y plane (a plane perpendicular to the first direction D1) is, for example, not less than 2×10³/cm² and not more than 2×10⁵/cm². If the density is too high, for example, parts of the plurality of structures 16 will tend to be continuous with each other. Crystallinity may decrease. If the density is too low, for example, the effect of stress relaxation will be reduced, and the effect of suppressing cracks will be reduced.

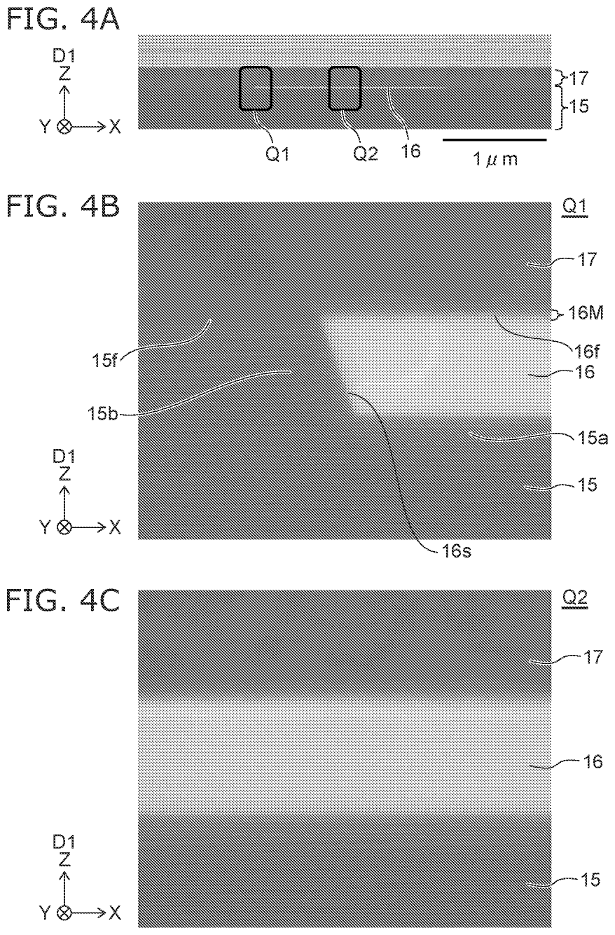

FIGS. 4A to 4C are microscopic images illustrating the wafer according to the first embodiment.

These figures are HAADF-STEM images of the cross section of the wafer 110. FIG. 4A is a HAADF-STEM image of a portion including one of the plurality of structures 16. FIG. 4B is an enlarged image of region Q1 in FIG. 4A. FIG. 4C is an enlarged image of region Q2 in FIG. 4A.

As shown in FIG. 4B, one of the plurality of structures 16 is provided between the first silicon region 15a and the first layer 17. The second silicon region 15b includes substrate face 15f facing first layer 17. One of the plurality of structures 16 includes a structure face 16f facing the first layer 17. A position of the substrate face 15f in the first direction D1 matches a position of the structure face 16f in the first direction D1. The upper face of the first silicon region 15a is aligned with the upper face of one of the plurality of structures 16.

As shown in FIG. 4B, one of the plurality of structures 16 includes a structure side face 16s facing the second silicon region 15b. The structure side face 16s is inclined with respect to the first direction D1. For example, the structure side face 16s is along the crystal plane of the silicon substrate 15. In one example, the structure side face 16s is along the (111) plane of the silicon substrate 15. In the plurality of structures 16 having high crystallinity, tilted structure side faces 16s along the crystal plane of the silicon substrate 15 are obtained.

As shown in FIGS. 4B and 4C, crystal lattices are observed in the plurality of structures 16.

As shown in FIG. 4B, an intermediate region 16M may be provided between the plurality of structures 16 and the first layer 17. The intermediate region 16M is, for example, a transition region. The intermediate region 16M will be described later.

Examples of elemental analysis results on the wafer 110 will be described below.

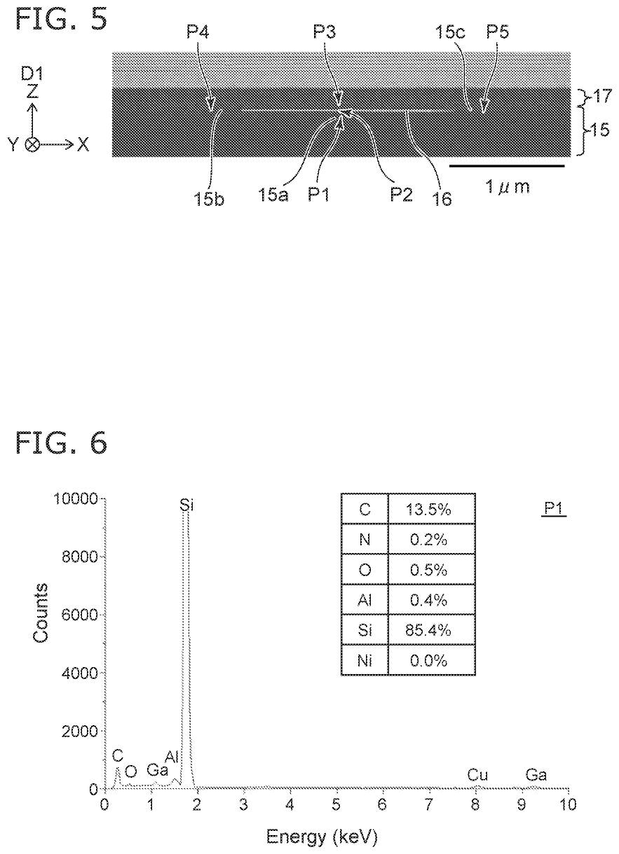

FIG. 5 is an image showing positions in the wafer according to the first embodiment.

FIGS. 6 to 10 are graphs illustrating element concentrations in the wafer according to the first embodiment.

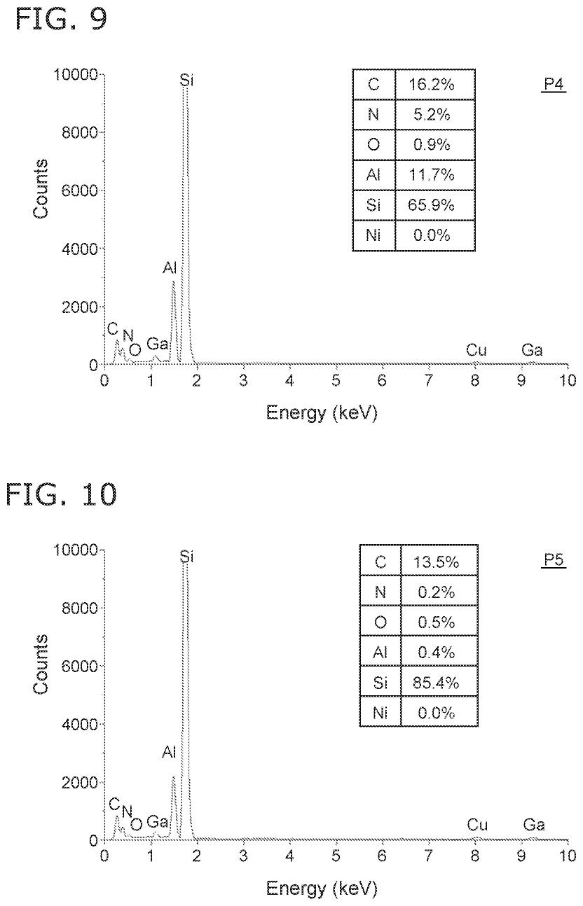

In FIG. 5, positions in the wafer 110 are shown in the same image as the HAADF-STEM image in FIG. 4A. FIG. 6 corresponds to the analysis result at the first position P1 shown in FIG. 5. FIG. corresponds to the analysis result at the second position P2 shown in FIG. 5. FIG. 8 corresponds to the analysis result at the third position P3 shown in FIG. 5. FIG. 9 corresponds to the analysis result at the fourth position P4 shown in FIG. 5. FIG. corresponds to the analysis result at the fifth position P5 shown in FIG. 5.

The first position P1 corresponds to the first silicon region 15a. The second position P2 corresponds to within one of the plurality of structures 16. The third position P3 corresponds to the first layer 17. There is the second position P2 between the first position P1 and the third position P3 in the Z-axis direction. The fourth position P4 corresponds to the second silicon region 15b. The fifth position P5 corresponds to the third silicon region 15c. FIGS. 6 to 10 are the results of analysis by TEM-EDX. In this example, the first element is Ni.

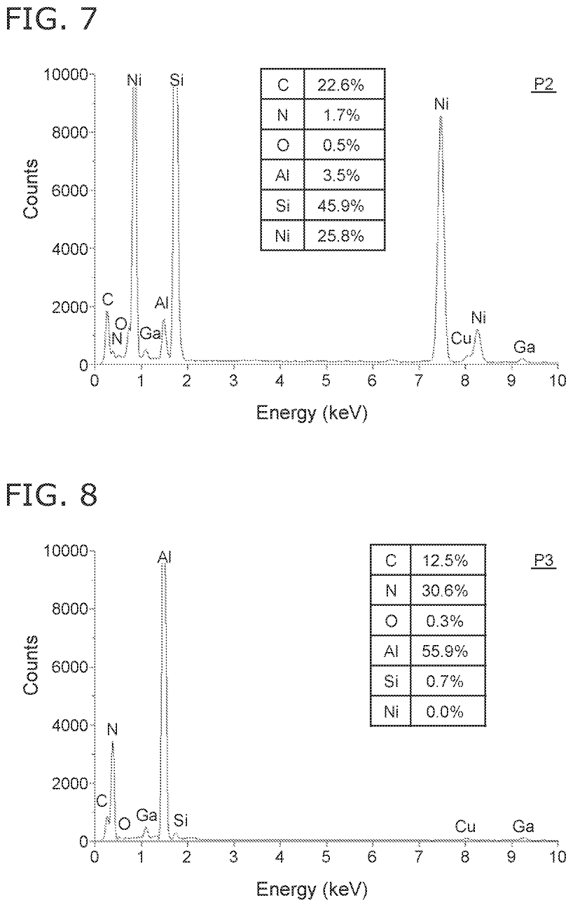

As shown in FIG. 7, the first element (Ni) is detected at the second position P2. In this example, the atomic concentration of Ni is 25.8 atm %. On the other hand, as shown in FIGS. 6 and 8, the first element (Ni) is not detected at the first position P1 and the third position P3. As shown in FIGS. 9 and 10, the first element (Ni) is not detected at the fourth position P4 and the fifth position P5 as well. The plurality of structures 16 being mutually discontinuous are formed.

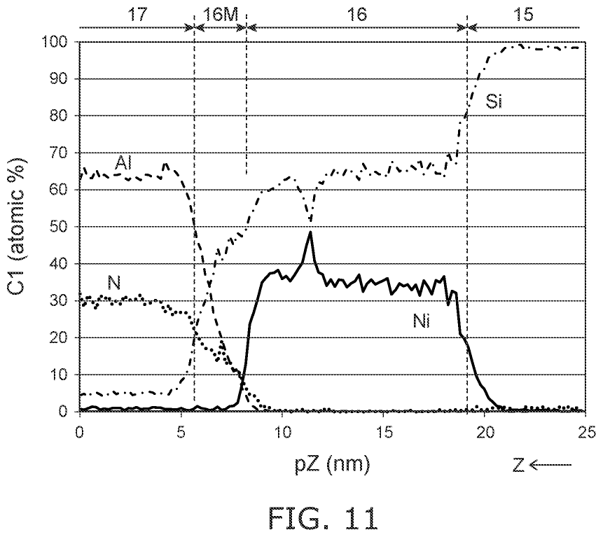

FIG. 11 is an elemental profile illustrating the wafer according to the first embodiment.

FIG. 11 illustrates the results of analyzing a cross section of one of the plurality of structures 16 of the wafer 110 using a three-dimensional atom probe tomography. The cross section is parallel to the first direction D1. The horizontal axis in FIG. 11 is the position pZ in the Z-axis direction. The vertical axis is the concentration C1 (atomic %) of the detected element.

As shown in FIG. 11, silicon is detected in the silicon substrate 15. In the first layer 17, Al and N are detected. In the structure 16, Ni (first element) and silicon are detected.

As shown in FIG. 11, the wafer 110 may include the intermediate region 16M (see FIG. 4B). The intermediate region 16M is provided between the plurality of structures 16 and a part of the first layer 17. As shown in FIG. 11, the intermediate region 16M includes Al, N and Si. The intermediate region 16M is, for example, a transition region.

The intermediate region 16M does not include the first element (for example, Ni). Alternatively, the concentration of the first element in the intermediate region 16M is lower than the concentration of the first element in the plurality of structures 16. As described below, carbon or the like may be detected in the intermediate region 16M.

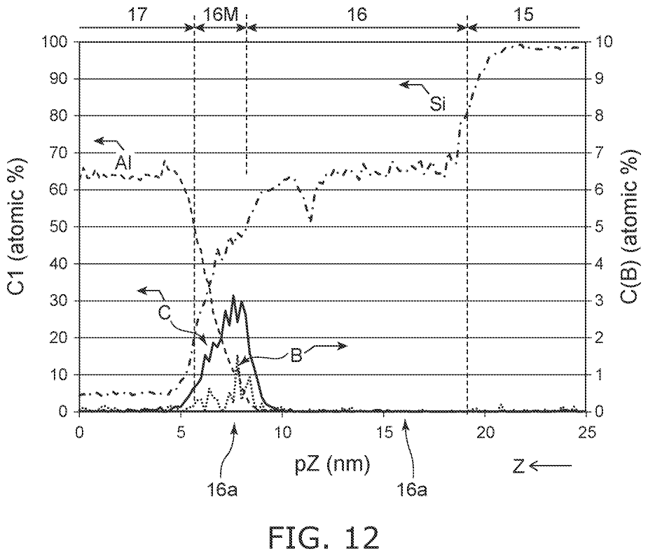

FIG. 12 is an elemental profile illustrating the wafer according to the first embodiment.

FIG. 12 illustrates the results of analyzing a cross section of one of the plurality of structures 16 of the wafer 110 using a three-dimensional atom probe tomography. The cross section is parallel to the first direction D1. The horizontal axis in FIG. 12 is the position pZ in the Z-axis direction. The left vertical axis is the concentration C1 (atomic %) of carbon, silicon, and Al. The right vertical axis is the boron concentration C (b) (atomic %). The profiles of silicon and Al in FIG. 12 are the same as the profiles of silicon and Al illustrated in FIG. 11.

As shown in FIG. 12, the intermediate region 16M may include carbon. On the other hand, the first layer 17 does not include carbon. Alternatively, the concentration of carbon in the first layer 17 is lower than the concentration of carbon in the intermediate region 16M. The plurality of structures 16 do not include carbon. Alternatively, the carbon concentration in the plurality of structures 16 is lower than the carbon concentration in the intermediate region 16M.

By providing the intermediate region 16M including carbon, better characteristics can be obtained. For example, carbon is locally present in the intermediate region 16M. For example, the adverse effects of carbon in the first layer 17 are suppressed. In the intermediate region 16M, the concentration of B may be locally high.

### Second Embodiment

The second embodiment relates to a semiconductor device.

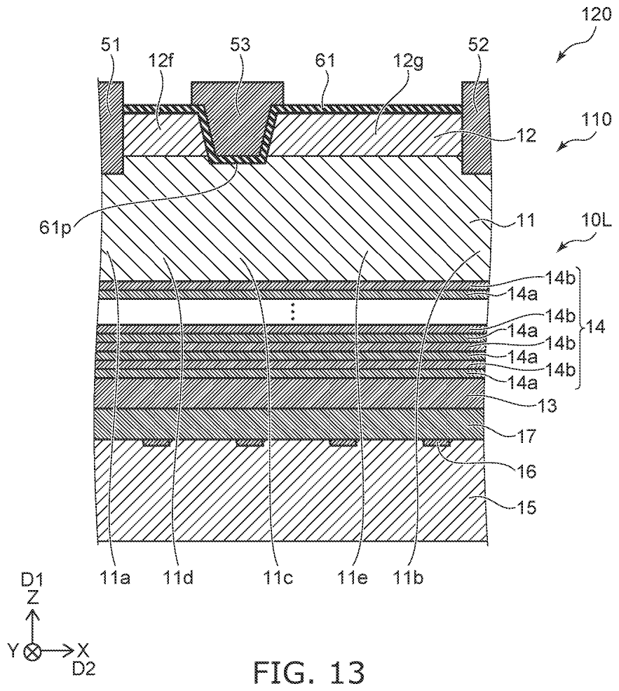

FIG. 13 is a schematic cross-sectional view illustrating a semiconductor device according to the second embodiment.

As shown in FIG. 13, a semiconductor device 120 according to the embodiment includes the wafer 110 according to the first embodiment, a first electrode 51, a second electrode 52, and a third electrode 53. The semiconductor device 120 may include an insulating member 61.

As already described, the wafer 110 includes the silicon substrate 15, the first layer 17, and the plurality of structures 16. In this example, the wafer 110 includes nitride layer 10L. The nitride layer 10L includes an AlGaN layer 13, a stacked structure 14, a first nitride region 11, and the like.

The stacked structure 14 includes a plurality of first films 14a and a plurality of second films 14b. One of the plurality of first films 14a is provided between one of the plurality of second films 14b and another one of the plurality of second films 14b. One of the plurality of second films 14b is provided between one of the plurality of first films 14a and another one of the plurality of first films 14a.

The AlGaN layer 13 is provided between the first layer 17 and the first nitride region 11. The stacked structure 14 is provided between the AlGaN layer 13 and the first nitride region 11.

The first nitride region 11 includes, for example, Alₓ₁Ga₁₋ₓ₁N (0≤x1<1). The composition ratio x1 is, for example, not less than 0 and not more than 0.15. The first nitride region 11 is, for example, a GaN layer.

In this example, nitride layer 10L includes a second nitride region 12. The second nitride region 12 includes, for example, Alₓ₂Ga₁₋ₓ₂N (0<x2≤1, x1<x2). The composition ratio x2 is, for example, higher than 0.15 and not less than 0.3. The second nitride region 12 is, for example, an AlGaN layer.

A first nitride region 11 is provided between the first layer and the second nitride region 12. A direction from the first electrode 51 to the second electrode 52 is along a second direction D2 crossing the first direction D1. The second direction D2 is, for example, the X-axis direction. A position of the third electrode 53 in the second direction D2 is between a position of the first electrode 51 in the second direction D2 and a position of the second electrode 52 in the second direction D2.

The first nitride region 11 includes a first partial region 11a, a second partial region 11b, a third partial region 11c, a fourth partial region 11d, and a fifth partial region 11e. A direction from the first partial region 11a to the first electrode 51 is along the first direction D1. A direction from the second partial region 11b to the second electrode 52 is along the first direction D1. The third partial region 11c is located between the first partial region 11a and the second partial region 11b in the second direction D2. A direction from the third partial region 11c to the third electrode 53 is along the first direction D1.

A position of the fourth partial region 11d in the second direction D2 is between a position of the first partial region 11a in the second direction D2 and a position of the third partial region 11c in the second direction D2. A position of the fifth partial region 11e in the second direction D2 is between the position of the third partial region 11c in the second direction D2 and a position of the second partial region 11b in the second direction D2.

The second nitride region 12 includes a sixth partial region 12f and a seventh partial region 12g. A direction from the fourth partial region 11d to the sixth partial region 12f is along the first direction D1. A direction from the fifth partial region 11e to the seventh partial region 12g is along the first direction D1.

For example, a current flowing between the first electrode and the second electrode 52 can be controlled by a potential of the third electrode 53. The potential of the third electrode 53 may be, for example, a potential based on a potential of the first electrode 51. The first electrode 51 functions, for example, as a source electrode. The second electrode 52 functions, for example, as a drain electrode. The third electrode 53 functions as, for example, a gate electrode. The semiconductor device is, for example, a transistor.

The first nitride region 11 includes a portion corresponding to second nitride region 12. A carrier region is formed in this portion. The carrier region is, for example, a two-dimensional electron gas. The semiconductor device 120 is, for example, a HEMT (High Electron Mobility Transistor).

As shown in FIG. 13, at least a part 61p of the insulating member 61 is provided between the nitride layer 10L and the third electrode 53. The insulating member 61 may be provided or omitted as required.

In the semiconductor device 120, at least a part of the third electrode 53 is provided between the sixth partial region 12f and the seventh partial region 12g in the second direction D2. At least a part of the third electrode 53 may be provided between the fourth partial region 11d and the fifth partial region 11e in the second direction D2. For example, a normally-off characteristic is obtained in the semiconductor device 120.

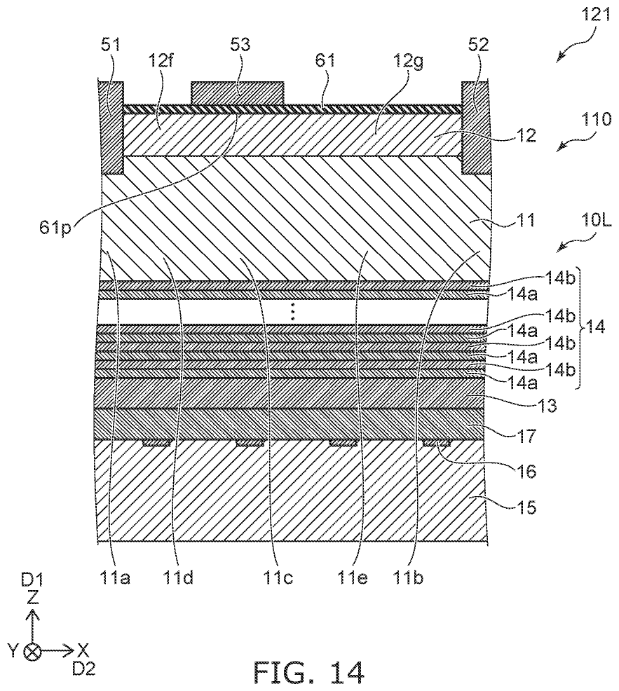

FIG. 14 is a schematic cross-sectional view illustrating a semiconductor device according to the second embodiment.

As shown in FIG. 14, a semiconductor device 121 according to the embodiment also includes the wafer 110, the first electrode 51, the second electrode 52, and the third electrode 53. In the semiconductor device 121, the second nitride region 12 is provided between the third partial region 11c and the third electrode 53 in the first direction D1. In the semiconductor device 121, normally-on operation is obtained.

In the semiconductor devices 120 and 121 according to the embodiment, for example, low on-resistance can be easily obtained based on high crystallinity. Cracks are suppressed.

In the embodiments, information regarding the shape and the like is obtained, for example, by electron microscopic observation. Information on composition and element concentration may be obtained by, for example, EDX (Energy Dispersive X-ray Spectroscopy) or SIMS (Secondary Ion Mass Spectrometry).

The embodiments may include the following configurations (e.g., technical proposals).

### (Configuration 1)

A wafer, comprising:
a silicon substrate;
a first layer including aluminum and nitrogen; and
a plurality of structures provided between a part of the silicon substrate and a part of the first layer in a first direction from the silicon substrate to the first layer,
the plurality of structures including a first element and silicon, the first element including at least one selected from the group consisting of Ni, Cu, Cr, Mn, Fe and Co, and
another part of the first layer being in contact with another part of the silicon substrate.

### (Configuration 2)

The wafer according to Configuration 1, wherein
the silicon substrate includes a first silicon region, a second silicon region, and a third silicon region,
in the first direction, the plurality of structures are provided between the first silicon region and the first layer, and
in a direction crossing the first direction, one of the plurality of structures is provided between the second silicon region and the third silicon region.

### (Configuration 3)

The wafer according to Configuration 2, wherein
the second silicon region includes a substrate face facing the first layer,
the one of the plurality of structures includes a structure face facing the first layer, and
a position of the substrate face in the first direction matches a position of the structure face in the first direction.

### (Configuration 4)

The wafer according to Configuration 2 or 3, wherein
a structure thickness of the one of the plurality of structures along the first direction is thinner than a first layer thickness of the first layer along the first direction.

### (Configuration 5)

The wafer according to Configuration 4, wherein
the structure thickness is not less than 5 nm and not more than 30 nm.

### (Configuration 6)

The wafer according to any one of Configurations 2-5, wherein
a structure length of the one structure of the plurality of structures in a direction perpendicular to the first direction is not less than 200 nm and not more than 5000 nm.

### (Configuration 7)

The wafer according to any one of Configurations 2-6, wherein
a density of the plurality of structures in a plane perpendicular to the first direction is not less than 2×10³/cm² and 2×10⁵/cm².

### (Configuration 8)

The wafer according to any one of Configurations 2-7, wherein
the one of the plurality of structures includes a structure side face facing the second silicon region, and
the structure side face is inclined with respect to the first direction.

### (Configuration 9)

The wafer according to any one of Configurations 2-7, wherein
the one of the plurality of structures includes a structure side face facing the second silicon region, and
the structure side face is along a crystal plane of the silicon substrate.

### (Configuration 10)

The wafer according to Configuration 9, wherein
the structure side face is along a (111) plane of the silicon substrate.

### (Configuration 11)

The wafer according to any one of Configurations 1-10, wherein
the plurality of structures include a crystal.

### (Configuration 12)

The wafer according to any one of Configurations 1-11, wherein
the plurality of structures are island-shaped.

### (Configuration 13)

The wafer according to any one of Configurations 1-12, wherein
the plurality of structures include a compound including Ni and silicon.

### (Configuration 14)

The wafer according to any one of Configurations 1-13, further comprising:
an intermediate region provided between the plurality of structures and the part of the first layer,
the intermediate region including Al, N and Si, and
the intermediate region not including the first element, or a concentration of the first element in the intermediate region being lower than a concentration of the first element in the plurality of structures.

### (Configuration 15)

The wafer according to Configuration 14, wherein
the intermediate region includes carbon, and
the first layer does not include carbon, or a concentration of carbon in the first layer is lower than a concentration of carbon in the intermediate region.

### (Configuration 16)

The wafer according to Configuration 14, wherein
the intermediate region includes carbon, and
the plurality of structures do not include carbon, or a concentration of carbon in the plurality of structures is lower than a concentration of carbon in the intermediate region.

### (Configuration 17)

The wafer according to any one of Configurations 1-16, further comprising:
a nitride layer,
the first layer being provided between the silicon substrate and the nitride layer, and
the nitride layer including nitrogen and at least one selected from the group consisting of Al and Ga.

### (Configuration 18)

A semiconductor device, comprising:
the wafer according to Configuration 17;
a first electrode;
a second electrode; and
a third electrode,
the nitride layer including
   a first nitride region including Alₓ₁Ga₁₋ₓ₁N (0≤x1 <1), and
   a second nitride region including Alₓ₂Ga₁₋ₓ₂N (0<x2≤1, x1<x2),
the first nitride region being provided between the first layer and the second nitride region,
a position of the third electrode in the second direction being between a position of the first electrode in the second direction and a position of the second electrode in the second direction,
the first nitride region including a first partial region, a second partial region, a third partial region, a fourth partial region, and a fifth partial region,
a direction from the first partial region to the first electrode being along the first direction,
a direction from the second partial region to the second electrode being along the first direction,
the third partial region being provided between the first partial region and the second partial region in the second direction,
a direction from the third partial region to the third electrode being along the first direction,
a position of the fourth partial region in the second direction being between a position of the first partial region in the second direction and a position of the third partial region in the second direction,
a position of the fifth partial region in the second direction being between the position of the third partial region in the second direction and a position of the second partial region in the second direction,
the second nitride region including a sixth partial region and a seventh partial region,
a direction from the fourth partial region to the sixth partial region being along the first direction, and
a direction from the fifth partial region to the seventh partial region being along the first direction.

### (Configuration 19)

The semiconductor device according to Configuration 18, further comprising:
an insulating member,
at least a part of the insulating member being provided between the nitride layer and the third electrode.

### (Configuration 20)

The semiconductor device according to Configuration 18 or 19, wherein
at least a part of the third electrode is provided between the sixth partial region and the seventh partial region in the second direction.

The tensile stress generated when the temperature is decreased from high temperature to room temperature can be reduced in the wafer 110, for example. The lattice constant (111) plane in the silicon substrate 15 may be 0.384 nm. The lattice constant of a-axis in the first layer 17 (AlN) may be 0.311 nm.

The lattice constant of (111) plane in NiSi₂ is 0.382 nm. The lattice constant of NiSi₂ is equivalent to the lattice constant of the silicon substrate 15. These lattice constant values are values at room temperature. The plurality of structures 16 may include, for example, a compound of Mn and silicon.

The plurality of first films 14a include, for example, Al_{z1}Ga_{1-z1}N (0<z1≤1). The composition ratio z1 is, for example, higher than 0.75 and not less than 1.0. In an example, the plurality of first films 14a are, for example, AlN layers. The plurality of second films 14b include, for example, Al_{z2}Ga_{1-Z2}N (0≤ z2<1, z2<z1). The composition ratio z2 is, for example, higher than 0.05 and not less than 0.3, in an example, the plurality of second films 14b are, for example, Al_{0.13}Ga_{0.87}N layers.

According to the embodiment, it is possible to provide a wafer and a semiconductor device whose characteristics can be improved.

In the specification of the application, the term “electrically connected state” includes a state in which a plurality of conductors are physically in contact and a current flows between the plurality of conductors. The term “electrically connected state” includes a state in which another conductor is inserted between the plurality of conductors and a current flows between the plurality of conductors.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the wafers such as substrates, layers and structures, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers and all semiconductor devices practicable by an appropriate design modification by one skilled in the art based on the wafers and the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a silicon substrate;
a first layer including aluminum and nitrogen; and
a plurality of structures provided between a part of the silicon substrate and a part of the first layer in a first direction from the silicon substrate to the first layer,
the plurality of structures including a first element and silicon, the first element including at least one selected from the group consisting of Ni, Cu, Cr, Mn, Fe and Co, and
another part of the first layer being in contact with another part of the silicon substrate.

2. The wafer according to claim 1, wherein
the silicon substrate includes a first silicon region, a second silicon region, and a third silicon region,
in the first direction, the plurality of structures are provided between the first silicon region and the first layer, and
in a direction crossing the first direction, one of the plurality of structures is provided between the second silicon region and the third silicon region.

3. The wafer according to claim 2, wherein
the second silicon region includes a substrate face facing the first layer,
the one of the plurality of structures includes a structure face facing the first layer, and
a position of the substrate face in the first direction matches a position of the structure face in the first direction.

4. The wafer according to claim 2, wherein
a structure thickness of the one of the plurality of structures along the first direction is thinner than a first layer thickness of the first layer along the first direction.

5. The wafer according to claim 4, wherein
the structure thickness is not less than 5 nm and not more than 30 nm.

6. The wafer according to claim 2, wherein
a structure length of the one structure of the plurality of structures in a direction perpendicular to the first direction is not less than 200 nm and not more than 5000 nm.

7. The wafer according to claim 2, wherein
a density of the plurality of structures in a plane perpendicular to the first direction is not less than 2×10³/cm² and 2×10⁵/cm².

8. The wafer according to claim 2, wherein
the one of the plurality of structures includes a structure side face facing the second silicon region, and
the structure side face is inclined with respect to the first direction.

9. The wafer according to claim 2, wherein
the one of the plurality of structures includes a structure side face facing the second silicon region, and
the structure side face is along a crystal plane of the silicon substrate.

10. The wafer according to claim 9, wherein
the structure side face is along a (111) plane of the silicon substrate.

11. The wafer according to claim 1, wherein
the plurality of structures include a crystal.

12. The wafer according to claim 1, wherein
the plurality of structures are island-shaped.

13. The wafer according to claim 1, wherein
the plurality of structures include a compound including Ni and silicon.

14. The wafer according to claim 1, further comprising:
an intermediate region provided between the plurality of structures and the part of the first layer,
the intermediate region including Al, N and Si, and
the intermediate region not including the first element, or a concentration of the first element in the intermediate region being lower than a concentration of the first element in the plurality of structures.

15. The wafer according to claim 14, wherein
the intermediate region includes carbon, and
the first layer does not include carbon, or a concentration of carbon in the first layer is lower than a concentration of carbon in the intermediate region.

16. The wafer according to claim 14, wherein
the intermediate region includes carbon, and
the plurality of structures do not include carbon, or a concentration of carbon in the plurality of structures is lower than a concentration of carbon in the intermediate region.

17. The wafer according to claim 1, further comprising:
a nitride layer,
the first layer being provided between the silicon substrate and the nitride layer, and
the nitride layer including nitrogen and at least one selected from the group consisting of Al and Ga.

18. A semiconductor device, comprising:
the wafer according to claim 17;
a first electrode;
a second electrode; and
a third electrode,
the nitride layer including
a first nitride region including Alₓ₁Ga₁₋ₓ₁N (0≤x1 <1), and
a second nitride region including Alₓ₂Ga₁₋ₓ₂N (0<x2≤1, x1<x2),
the first nitride region being provided between the first layer and the second nitride region,
a position of the third electrode in the second direction being between a position of the first electrode in the second direction and a position of the second electrode in the second direction,
the first nitride region including a first partial region, a second partial region, a third partial region, a fourth partial region, and a fifth partial region,
a direction from the first partial region to the first electrode being along the first direction,
a direction from the second partial region to the second electrode being along the first direction,
the third partial region being provided between the first partial region and the second partial region in the second direction,
a direction from the third partial region to the third electrode being along the first direction,
a position of the fourth partial region in the second direction being between a position of the first partial region in the second direction and a position of the third partial region in the second direction,
a position of the fifth partial region in the second direction being between the position of the third partial region in the second direction and a position of the second partial region in the second direction,
the second nitride region including a sixth partial region and a seventh partial region,
a direction from the fourth partial region to the sixth partial region being along the first direction, and
a direction from the fifth partial region to the seventh partial region being along the first direction.

19. The device according to claim 18, further comprising:
an insulating member,
at least a part of the insulating member being provided between the nitride layer and the third electrode.

20. The device according to claim 18, wherein
at least a part of the third electrode is provided between the sixth partial region and the seventh partial region in the second direction.
